(19) United States
(12) Patent Application Publication
(10) Pub. No.: US 2023/0128736 A1
(43) Pub. Date: Apr. 27, 2023

(54) METHOD FOR TESTING LIGHT-EMITTING DIODE, AND A PLASMA GENERATING DEVICE FOR IMPLEMENTING THE METHOD

(71) Applicant: Ming Chi University of Technology, New Taipei City (TW)

(72) Inventors: Jang-Hsing HSIEH, New Taipei City (TW); Yi-Jin WEI, New Taipei City (TW)

(21) Appl. No.: 17/699,473

(22) Filed: Mar. 21, 2022

(30) Foreign Application Priority Data
Oct. 26, 2021 (TW) 110139618

(51) Int. Cl. G01R 31/26; H01J 37/32

(52) U.S. Cl. CPC G01R 31/2635; H01J 37/32568; H01J 37/32577; H01J 37/3244

(57) ABSTRACT

A method for testing a light-emitting diode (LED) includes steps of providing a plasma generating device in proximity to a device under test (DUT) that includes the LED and a conductive port which are electrically connected to each other, and utilizing the plasma generating device to emit a plasma beam toward the conductive port of the DUT to cause generation of a positive voltage on the LED for testing the LED.

### CROSS-REFERENCE TO RELATED APPLICATION

This application claims priority of Taiwanese Invention Patent Application No. 110139618, filed on Oct. 26, 2021.

### FIELD

The disclosure relates to a method for testing a light-emitting diode, and a plasma generating device for implementing the method.

### BACKGROUND

Conventionally, a contact probe is utilized to test a light-emitting diode (LED). Since an electrical circuit of an LED device is becoming more and more complex and elaborate, size reduction of the contact probe is demanded. However, miniaturization of the size of the contact probe has a limit (e.g., ultimate limit defined by the distance of atoms in the material). Moreover, the smaller the size of the contact probe, the more expensive it is and the more likely it is to wear out.

### SUMMARY

Therefore, an object of the disclosure is to provide a method for testing a light-emitting diode (LED) and a plasma generating device that can alleviate at least one of the drawbacks of the prior art.

According to one aspect of the disclosure, the method includes steps of providing a plasma generating device in proximity to a device under test (DUT) which includes the LED and a conductive port that are electrically connected to each other, and utilizing the plasma generating device to emit a plasma beam toward the conductive port of the DUT to cause generation of a positive voltage on the LED for testing the LED. The plasma generating device includes a tube that is made of a dielectric material, that is configured to allow passage of a reactant gas, and that has a first end formed with an opening for emitting the plasma beam generated from the reactant gas and a second end opposite to the first end. The step of providing a plasma generating device is to place the tube to have the first end thereof spaced apart from the conductive port of the DUT by a predefined distance. The plasma generating device further includes an electrode unit that includes an inner electrode extending into the tube through the second end of the tube, and an outer electrode surrounding the tube and disposed between the inner electrode and the first end of the tube. The inner electrode and the outer electrode, when being electrified, cooperatively generate an electric field through the reactant gas passing through the tube so to generate plasma to be emitted through the opening at the first end as the plasma beam.

According to another aspect of the disclosure, the plasma generating device includes a gas source, a tube, an electrode unit and a power supply.

The tube is made of a dielectric material, is in spatial communication with the gas source, and has a first end formed with an opening for emitting a plasma beam and a second end opposite to the first end.

The electrode unit includes an inner electrode and an outer electrode. The inner electrode extends into the tube through the second end of the tube. The outer electrode surrounds the tube and is disposed between the inner electrode and the first end of the tube.

The power supply is electrically connected to the inner electrode and the outer electrode.

The gas source is configured to supply a reactant gas to the tube. The tube is configured to allow passage of the reactant gas. The power supply is configured to supply electric power having a waveform of a square wave to the inner electrode and the outer electrode to make the inner electrode and the outer electrode cooperatively generate an electric field through the reactant gas passing through the tube so to generate plasma to be emitted through the opening at the first end as the plasma beam.

### BRIEF DESCRIPTION OF THE DRAWINGS

Other features and advantages of the disclosure will become apparent in the following detailed description of the embodiments with reference to the accompanying drawings, of which:

FIG. 1 is a schematic diagram illustrating a plasma generating device according to an embodiment of the disclosure;

FIG. 2 is a fragmentary cross-sectional view of a part of the plasma generating device according to the embodiment of the disclosure; and

FIG. 3 is a flow chart illustrating a method for testing a light-emitting diode (LED) according to an embodiment of the disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

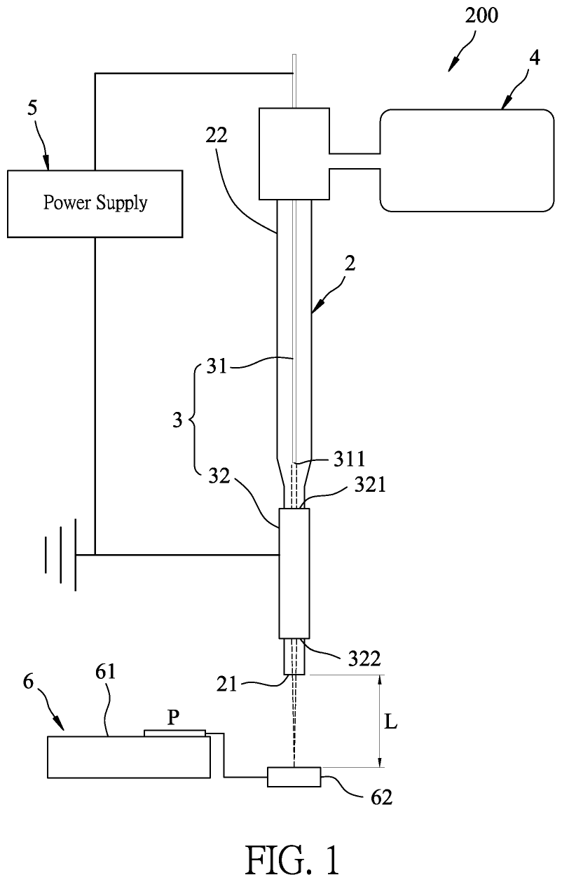

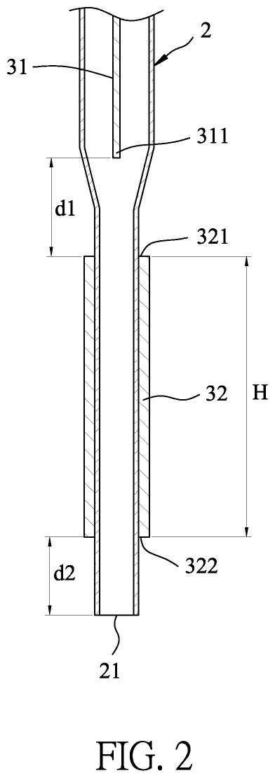

Referring to FIGS. 1 and 2, an embodiment of a plasma generating device 200 according to the disclosure is illustrated. The plasma generating device 200 is utilized to implement a method for testing a light-emitting diode (LED).

In particular, a device under test (DUT) 6 including an LED 61 and a conductive port 62 is to be tested by using the plasma generating device 200. The LED 61 and the conductive port 62 are electrically connected to each other. In this embodiment, the conductive port 62 of the DUT 6 is an external electrode that is electrically connected to an anode (P) of the LED 61.

The plasma generating device 200 includes a gas source 4, a tube 2, an electrode unit 3 and a power supply 5.

The gas source 4 contains a reactant gas therein, and is configured to supply the reactant gas to the tube 2. The reactant gas is inert gas such as helium gas, neon gas and argon gas, but is not limited to the disclosure herein. Since a breakdown voltage of inert gas is lower than that of non-inert gas, inert gas can be dissociated to become plasma (which includes a large number of charged particles such as ions and electrons) under a relatively low voltage, and so the plasma thus generated may be maintained at a relatively low temperature (about 40 to 50° C.) during the generation of the plasma.

The tube 2 has a shape of a hollow column, and is in spatial communication with the gas source 4 for receiving the reactant gas therefrom. The tube 2 is configured to allow passage of the reactant gas supplied by the gas source 4. It is worth to note that the gas source 4 is configured to adjust a volumetric flow rate of supplying the reactant gas into the tube 2, thereby varying air pressure in the tube 2. The tube 2 has a first end 21 formed with an opening for emitting a plasma beam generated from the reactant gas, and a second end 22 opposite to the first end 21. The opening at the first end 21 of the tube 2 has a diameter ranging from 0.3 to 0.6 mm. The tube 2 is made of a dielectric material such as quartz, but is not limited to the disclosure herein and may vary in other embodiments.

The electrode unit 3 includes an inner electrode 31 and an outer electrode 32. The inner electrode 31 and the outer electrode 32 are each made of an electrically conductive material (e.g., metal, alloy, etc.), and they may be made of the same material or different materials. The inner electrode 31 and the outer electrode 32 are separated by the tube 2.

Specifically, the inner electrode 31 has a shape of a long needle, and extends into the tube 2 through the second end 22 of the tube 2. The outer electrode 32 surrounds the tube 2, and is disposed between the inner electrode 31 and the first end 21 of the tube 2 in an extension direction of the tube 2. The inner electrode 31 and the outer electrode 32 are spaced apart from each other by a distance (d1) ranging from 5 to 45 mm in the extension direction of the tube 2. The outer electrode 32 extends in the extension direction of the tube 2 and has a dimension (H) ranging from 10 to 70 mm in the extension direction. In some embodiments, the distance (d1) between the inner electrode 31 and the outer electrode 32 ranges preferably from 35 to 45 mm. In some embodiments, the dimension (H) of the outer electrode 32 in the extension direction ranges preferably from 10 to 40 mm.

More specifically, the inner electrode 31 has a tip 311 in proximity to the outer electrode 32. The outer electrode 32 has a first rim 321 in proximity to the inner electrode 31. The tip 311 of the inner electrode 31 is spaced apart from the first rim 321 of the outer electrode 32 by the distance (d1) in the extension direction of the tube 2.

It is worth to note that keeping the tip 311 of the inner electrode 31 and the first rim 321 of the outer electrode 32 spaced apart by an appropriate distance would make the plasma generating device 200 have relatively great efficiency of energy conversion, and keep laminar flow of the reactant gas in the tube 2 steady. In a condition that the tip 311 of the inner electrode 31 and the first rim 321 of the outer electrode 32 are too close to each other or even overlap with each other in the extension direction of the tube 2, the electrode unit 3 is likely to generate an electric arc, and thus the reactant gas in the tube 2 would be disturbed to form a turbulence. In a condition that the tip 311 of the inner electrode 31 and the first rim 321 of the outer electrode 32 are too far from each other, the plasma beam generated by the plasma generating device 200 would not have sufficient intensity to satisfy testing needs.

The outer electrode 32 further has a second rim 322 in proximity to the first end 21 of the tube 2. The second rim 322 of the outer electrode 32 is spaced apart from the first end 21 by a distance (d2) ranging from 2 to 5 mm in the extension direction of the tube 2.

It is worth noting that when the distance (d2) between the second rim 322 of the outer electrode 32 and the first end 21 is smaller than 2 mm, the plasma beam may have an extremely high temperature and may cause damage to the DUT 6. On the other hand, when the distance (d2) between the second rim 322 of the outer electrode 32 and the first end 21 is greater than 5 mm, the plasma beam would not have sufficient intensity to satisfy testing needs, and the state of the plasma beam thus generated may not be steady.

It should be noted that the dimension (H) of the outer electrode 32, the distance (d1) between the tip 311 of the inner electrode 31 and the first rim 321 of the outer electrode 32, and the distance (d2) between the second rim 322 of the outer electrode 32 and the first end 21 of the tube 2 can be modified according to practical needs during testing.

The power supply 5 is electrically connected to the inner electrode 31 and the outer electrode 32. The power supply 5 is configured to supply electric power having a waveform of a square wave to the inner electrode 31 and the outer electrode 32. When being electrified by the power supply 5, point discharge effect occurs at the tip 311 of the inner electrode 31, and the inner electrode 31 and the outer electrode 32 cooperatively generate an electric field through the reactant gas passing through the tube 2 so to generate plasma to be emitted through the opening at the first end 21 as the plasma beam.

Specifically, when the reactant gas is affected by the electric field, particles of the reactant gas collide with each other, and thus the reactant gas are dissociated to become plasma. Then, the plasma in the tube 2 is driven by the electric field and incoming reactant gas from the gas source 4 to flow toward the opening at the first end 21, and is then emitted through the opening as the plasma beam.

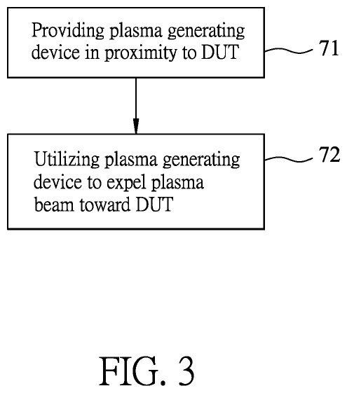

Referring to FIG. 3, an embodiment of the method for testing an LED 61 according to the disclosure is illustrated. The method includes steps 71 and 72 delineated below.

In step 71, the plasma generating device 200 that has been described is provided in proximity to the DUT 6.

The tube 2 is to be so placed that the first end 21 thereof is spaced apart from the conductive port 62 of the DUT 6 by a predefined distance (L) (see FIG. 1). The predefined distance (L) between the first end 21 of the tube 2 and the conductive port 62 of the DUT 6 is not greater than 15 mm.

Specifically, the first end 21 of the tube 2 is spaced apart from the conductive port 62 of the DUT 6 by the predefined distance (L) that ranges from 5 to 10 mm. Preferably, the predefined distance (L) ranges from 5 to 8 mm.

In step 72, the plasma generating device 200 is utilized to emit the plasma beam toward the conductive port 62 of the DUT 6 to cause generation of a positive voltage on the LED 61 for testing the LED 61.

Specifically, the gas source 4 is used to supply the reactant gas to the tube 2 with a volumetric flow rate ranging from 0.5 to 2.5 slm. It should be noted that when the volumetric flow rate of supplying the reactant gas is too low, a plasma beam generated by the plasma generating device 200 would have an insufficient intensity (i.e., an electron density of the plasma beam is less than 10¹⁶ particles per cubic centimeter) and would be unable to cause generation of a positive voltage on the LED 61. When the volumetric flow rate of supplying the reactant gas is too high, the reactant gas in the tube 2 would be disturbed to form a turbulence, adversely affecting the stability of the plasma beam.

The power supply 5 is used to supply electric power to the electrode unit 3. Specifically, the electric power has a waveform of a square wave, a peak voltage ranging from 5 to 8 kV, and a frequency (i.e., pulse repetition frequency) ranging from 10 to 20 KHz. It should be noted that when the frequency of the electric power is too low, ions and electrons dissociated from the reactant gas would dissipate before a next pulse of the electric power is applied to the reactant gas, and thus the plasma beam cannot be steadily generated. Oppositely, when the frequency of the electric power is too high, the plasma beam would have an extremely high energy and an extremely high temperature, and may cause damage to the DUT 6.

When the plasma generating device 200 is prepared in the previously disclosed manner, the plasma generating device 200 is able to generate a plasma beam that has a diameter not greater than 0.5 mm and that has a sufficient intensity (i.e., an electron density not less than 10¹⁶ particles per cubic centimeter), and is able to emit the plasma beam toward the conductive port 62 of the DUT 6 to cause generation of a positive voltage on the LED 61 of the DUT 6.

When the LED 61 is normal, the LED 61 conducts electricity and will light up. When the LED 61 is abnormal, the LED 61 will not light up. Consequently, determination as to whether the LED 61 is normal can be made by observing whether the LED 61 lights up or not. Moreover, brightness of light emitted by the LED 61 can be used to determine quality of the LED 61.

It should be noted that in a scenario where the predefined distance (L) is abnormally large, a portion of high-energy particles in the plasma beam emitted from the opening at the first end 21 of the tube 2 would dissipate before arriving at the conductive port 62 of the DUT 6. Consequently, an intensity of the plasma beam striking the conductive port 62 would be insufficient for causing generation of a positive voltage on the LED 61, and accuracy of testing the LED 61 would be adversely affected.

For the purpose of explanation, two examples of applying the method according to the disclosure will be described in the following paragraphs. The DUT 6 as previously described is to be tested in these examples.

In a first example, placement of the tube 2 is that the first end 21 thereof is spaced apart from the conductive port 62 of the DUT 6 by about 8 mm (i.e., the predefined distance (L) is about 8 mm). The tip 311 of the inner electrode 31 is spaced apart from the first rim 321 of the outer electrode 32 by about 35 mm in the extension direction of the tube 2 (i.e., the distance (d1) is about 35 mm). The second rim 322 of the outer electrode 32 is spaced apart from the first end 21 of the tube 2 by about 5 mm in the extension direction of the tube 2 (i.e., the distance (d2) is about 5 mm). The dimension (H) of the outer electrode 32 in the extension direction of the tube 2 is 30 mm. The gas source 4 supplies helium gas to the tube 2 with a volumetric flow rate of 0.5 slm. The power supply 5 supplies, to the electrode unit 3, the electric power having a peak voltage of 5 kV and a frequency of 16 KHz.

When the plasma generating device 200 is prepared in the above-mentioned manner of the first example, the plasma generating device 200 is capable of emitting a plasma beam that has a diameter of about 0.5 mm and a temperature of 45° C. toward the conductive port 62 of the DUT 6, resulting in generation of a positive voltage on the LED 61 of the DUT 6.

In a second example, the plasma generating device 200 is prepared in a manner similar to that in the first example. For the sake of brevity, only differences between the first example and the second example are described herein. The gas source 4 supplies argon gas to the tube 2 with a volumetric flow rate of 0.5 slm. The power supply 5 supplies, to the electrode unit 3, the electric power having a peak voltage of 6 kV and a frequency of 19 KHz. In this way, the plasma generating device 200 is capable of emitting a plasma beam toward the conductive port 62 of the DUT 6, resulting in generation of a positive voltage on the LED 61 of the DUT 6.

A conventional approach to steadily generating a plasma beam with a diameter not greater than 1 cm is realized by increasing the peak voltage of the electric power applied to the electrodes or by increasing the temperature of the reactant gas. However, the plasma beam generated in the conventional approach has an extremely high temperature and may cause damage to a DUT. Alternatively, for a plasma beam that is generated under atmospheric pressure of one standard atmosphere (i.e., 1 atm) and that has a temperature not greater than 50° C., stability of the plasma beam cannot be maintained, and hence accuracy of testing by using the plasma beam may be adversely affected.

In comparison, the plasma generating device 200 according to the disclosure is capable of generating a plasma beam that has a diameter not greater than 0.5 mm by arranging relative positions of the inner electrode 31 and the outer electrode 32, by using inert gas as the reactant gas, by adjusting the volumetric flow rate of supplying the reactant gas, by designing the size of the outer electrode 32 and the tube 2, by setting parameters (e.g., the waveform, the peak voltage and the frequency) of the electric power supplied by the power supply 5, and by adjusting the predefined distance (L) between the first end 21 of the tube 2 and the conductive port 62 of the DUT 6. The plasma beam thus generated can be used to cause generation of a positive voltage on the LED for testing the LED. Since the plasma beam has a diameter not greater than 0.5 mm, a cross-section thereof is relatively small, and the plasma beam is more suitable than a contact probe for testing of a small-sized LED or other small-sized electronic devices. It is worth to note that the plasma generating device 200 according to the disclosure can generate the plasma beam in a steady way, and the plasma beam thus generated has a relatively low temperature, which is not greater than 50° C., and an electron temperature (Te) ranging from 0.2 to 0.4 eV. Therefore, accuracy of testing may be ensured, and damage caused by the plasma beam to the LED may be prevented. Moreover, issues of abrasion of a contact probe and the DUT 6 would not occur in the method according to the disclosure, and thus costs arising from testing may be reduced.

In the description above, for the purposes of explanation, numerous specific details have been set forth in order to provide a thorough understanding of the embodiments. It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects, and that one or more features or specific details from one embodiment may be practiced together with one or more features or specific details from another embodiment, where appropriate, in the practice of the disclosure.

While the disclosure has been described in connection with what are considered the exemplary embodiments, it is understood that this disclosure is not limited to the disclosed embodiments but is intended to cover various arrangements included within the spirit and scope of the broadest interpretation so as to encompass all such modifications and equivalent arrangements.

What is claimed is:

1. A method for testing a light-emitting diode (LED), comprising steps of:
providing a plasma generating device in proximity to a device under test (DUT), the DUT including the LED and a conductive port that are electrically connected to each other, the plasma generating device including
a tube that is made of a dielectric material, that is configured to allow passage of a reactant gas, and that has a first end formed with an opening for emitting a plasma beam generated from the reactant gas and a second end opposite to the first end, wherein the step of providing a plasma generating device is to place the tube to have the first end thereof spaced apart from the conductive port of the DUT by a predefined distance, and
an electrode unit that includes an inner electrode extending into the tube through the second end of the tube, and an outer electrode surrounding the tube and disposed between the inner electrode and the first end of the tube, wherein the inner electrode and the outer electrode, when being electrified, cooperatively generate an electric field through the reactant gas passing through the tube so to generate plasma to be emitted through the opening at the first end as the plasma beam; and
utilizing the plasma generating device to emit the plasma beam toward the conductive port of the DUT to cause generation of a positive voltage on the LED for testing the LED.

2. The method as claimed in claim 1, wherein, in the step of providing a plasma generating device:
the opening at the first end of the tube has a diameter ranging from 0.3 to 0.6 mm;
the inner electrode and the outer electrode are spaced apart from each other by a distance ranging from 5 to 45 mm in an extension direction of the tube; and
the predefined distance between the first end of the tube and the conductive port of the DUT is not greater than 15 mm.

3. The method as claimed in claim 1, wherein, in the step of providing a plasma generating device:
the inner electrode has a tip in proximity to the outer electrode, the outer electrode has a rim in proximity to the inner electrode, and the tip is spaced apart from the rim by a distance ranging from 35 to 45 mm in an extension direction of the tube.

4. The method as claimed in claim 1, wherein, in the step of providing a plasma generating device:
the outer electrode has a rim in proximity to the first end of the tube, and the rim is spaced apart from the first end by a distance ranging from 2 to 5 mm in an extension direction of the tube.

5. The method as claimed in claim 1, wherein, in the step of providing a plasma generating device, the tube is placed so that the first end thereof is spaced apart from the conductive port of the DUT by the predefined distance that ranges from 5 to 10 mm.

6. The method as claimed in claim 1, wherein the conductive port of the DUT is an external electrode that is electrically connected to an anode of the LED.

7. The method as claimed in claim 1, wherein:
in the step of providing a plasma generating device, the plasma generating device further includes a power supply that is electrically connected to the inner electrode and the outer electrode, and a gas source that is in spatial communication with the tube and that contains the reactant gas therein; and
the step of utilizing the plasma generating device includes steps of
using the gas source to supply the reactant gas to the tube with a volumetric flow rate ranging from 0.5 to 2.5 slm, and
using the power supply to supply, to the electrode unit, electric power having a waveform of a square wave, a peak voltage ranging from 5 to 8 kV, and a frequency ranging from 10 to 20 KHz.

8. A plasma generating device, comprising:
a gas source that contains a reactant gas therein;
a tube that is made of a dielectric material, that is in spatial communication with said gas source for receiving the reactant gas therefrom, that is configured to allow passage of the reactant gas, and that has a first end formed with an opening for emitting a plasma beam generated from the reactant gas and a second end opposite to said first end;
an electrode unit that includes an inner electrode extending into said tube through said second end of said tube, and an outer electrode surrounding said tube and disposed between said inner electrode and said first end of said tube; and
a power supply that is electrically connected to said inner electrode and said outer electrode, wherein said power supply is configured to supply electric power having a waveform of a square wave to said inner electrode and said outer electrode to make said inner electrode and said outer electrode cooperatively generate an electric field through the reactant gas passing through said tube so as to generate plasma to be emitted through said opening at said first end as the plasma beam.

9. The plasma generating device as claimed in claim 8, wherein said opening at said first end of said tube has a diameter ranging from 0.3 to 0.6 mm, and said inner electrode and said outer electrode are spaced apart from each other by a distance ranging from 5 to 45 mm in an extension direction of said tube.

10. The plasma generating device as claimed in claim 8, wherein said inner electrode has a tip in proximity to said outer electrode, said outer electrode has a rim in proximity to said inner electrode, and said tip is spaced apart from said rim by a distance ranging from 35 to 45 mm in an extension direction of said tube.

11. The plasma generating device as claimed in claim 8, wherein said outer electrode has a rim in proximity to said first end of said tube, and said rim is spaced apart from said first end by a distance ranging from 2 to 5 mm in an extension direction of said tube.

12. The plasma generating device as claimed in claim 8, wherein said gas source is configured to supply the reactant gas to said tube with a volumetric flow rate ranging from 0.5 to 2.5 slm.

13. The plasma generating device as claimed in claim 8, wherein said power supply is configured to supply the electric power having a peak voltage ranging from 5 to 8 kV and a frequency ranging from 10 to 20 KHz.
